(19) United States
(12) Patent Application Publication
(10) Pub. No.: US 2017/0229377 A1
(43) Pub. Date: Aug. 10, 2017

(54) LIQUID MANIFOLD STRUCTURE FOR DIRECT COOLING OF LIDDED ELECTRONICS MODULES

(71) Applicant: International Business Machines Corporation, Armonk, NY (US)

(72) Inventors: Michael J. Ellsworth, JR., Lagrangeville, NY (US); Allan C. VanDeventer, Poughkeepsie, NY (US); Jason T. Wertz, Pleasant Valley, NY (US)

(21) Appl. No.: 15/015,521

(22) Filed: Feb. 4, 2016

(51) Int. Cl. H01L 23/473; F28F 9/02; H01L 23/367; H01L 23/373; H01L 23/10; H01L 23/40

(52) U.S. Cl. CPC H01L 23/473; H01L 23/10; H01L 23/4093; H01L 23/3672; H01L 23/3677; H01L 23/3737; H01L 23/3736; F28F 9/026

(57) ABSTRACT

Embodiments of the present invention provide efficient and cost-effective systems for a lidded electronic device. The lidded electronic device includes an electronic module including an integrated circuit chip built on a substrate. The lidded electronic device also includes a module lid having a heat transferring feature, which extends above the top surface of the module lid. A manifold structure can be placed over the top surface of the module lid using a variety of techniques.

### BACKGROUND OF THE INVENTION

The present invention relates generally to the field of lidded electronic modules, and more particularly to a liquid manifold structure for direct cooling of lidded electronic modules.

In order to achieve increases in processor performance, there is often an increase in power dissipation of integrated circuit chips, as well as the modules containing the chips. This leads to a cooling challenge, which can bring up material, electrical, and serviceability concerns. Liquid (i.e., water) cold plates are often used to cool electronic components, such as server processors. Various thermal interface materials are often placed between the module lid and the bottom of the cold plate, in order to help cool the electronic components.

### SUMMARY

According to an embodiment of the present invention, a lidded electronic device is provided, the lidded electronic device comprising: an electronic module, the electronic module comprising an integrated circuit chip coupled to a substrate; a module lid, wherein the module lid comprises a heat transferring feature, and wherein the heat transferring feature is configured to extend above a top surface of the module lid; and a manifold structure placed over the top surface of the module lid.

According to another embodiment of the present invention, a method for directing water flow in an electronic device is provided, the method comprising: based in part on a power map of an electronic device, configuring at least one of: a manifold structure and a heat transferring structure; allowing water to flow through an inlet within the manifold structure, wherein the water is directed first to a point of the electronic device with a highest temperature; and allowing the water to flow through an outlet within the manifold structure.

According to another embodiment of the present invention, a lidded electronic device is provided, the lidded electronic device comprising: an electronic module, the electronic module comprising an integrated circuit chip coupled to a substrate; a module lid, wherein the module lid is fitted over the integrated circuit chip, and wherein the module lid and the integrated circuit chip are coupled to a TIM1; and a manifold structure placed over a top surface of the module lid.

### BRIEF DESCRIPTION OF THE DRAWINGS

FIG. 1 depicts a cross-sectional view of a water cooled module with integrated heat transferring structures, in accordance with an embodiment of the present invention;

FIG. 2 depicts a partially exploded view of a more detailed embodiment of a water cooled module with integrated heat transferring structures, in accordance with an embodiment of the present invention; and

FIG. 3 depicts a plan view of an example defined flow path integrated into a module lid, in accordance with one embodiment of the present invention.

### DETAILED DESCRIPTION

Liquid cold plates are often used to cool electronic components, such as server processors. Various thermal interface materials are often placed between the module lid and the bottom of the cold plate, in order to help cool the electronic components. Often, heat transfer is reduced, due to the water not being in direct contact with the module lid surface. Embodiments of the present invention provide a liquid manifold structure for direct cooling of lidded electronic modules, by passing fluid over the top surface of an integrated lid module.

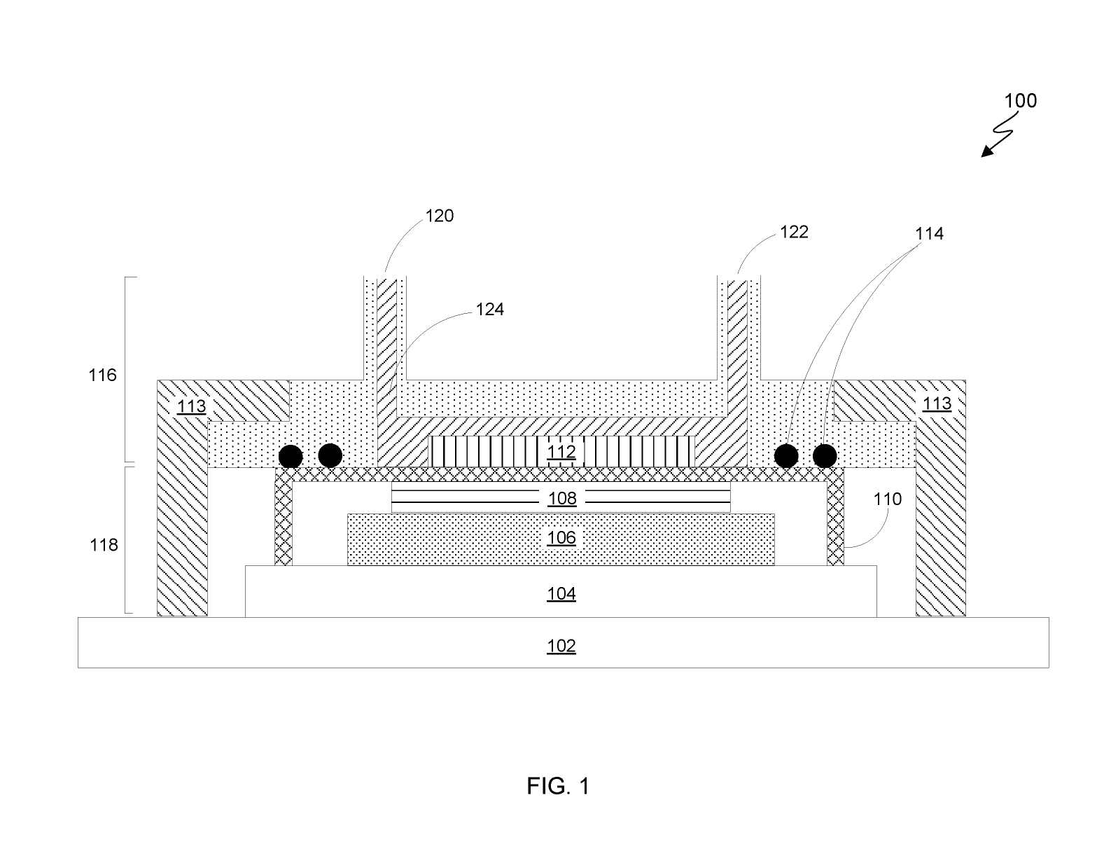

FIG. 1 depicts a cross-sectional view 100 of a water cooled module 118 with integrated heat transferring structures, in accordance with an embodiment of the present invention.

Water cooled module 118 includes module lid 110, which encloses an electronic component, such as an integrated circuit chip 106 or stack of integrated circuit chips. Integrated circuit chip 106 resides on, or is supported by, substrate 104, to which, in this exemplary embodiment, module lid 110 is coupled. Integrated within water cooled module 118 is a thermal interface material (TIM1) 108, which is used as a layer below the module lid to increase thermal transfer efficiency. In this exemplary embodiment, heat transferring features, such as fins 112, are constructed to extend above the top surface of module lid 110. Fins 112 are used to improve heat transfer.

A water carrying manifold structure 116 is detachably coupled to water cooled module 118 using clamping features 113. Clamping features 113 can include any clamping or retention mechanism known in the art. In this exemplary embodiment, clamping features 113 are used to provide the force to seal manifold structure 116 to module lid 110, and to ensure an electrical connection is formed by pushing integrated circuit chip 106 to board 102. In another embodiment, integrated circuit chip 106 secures itself to board 102 using a clamping mechanism, and clamping features 113 provide a seal between manifold structure 116 and module lid 110. In some embodiments, manifold structure 116 can be mechanically attached to module lid 110 using screws, clips, or any other known attachment method in the art. In this exemplary embodiment, manifold structure 116 is removable and/or serviceable. Manifold structure 116 may include sealing features 114, such as O-rings or gaskets, to prevent coolant from leaking at the passageway interfaces of the manifold structure 116 and the water cooled module 118. A fluid, such as water 124, is able to flow from an inlet 120 to an outlet 122 via permanently attached or separable tubes that extend from manifold structure 116.

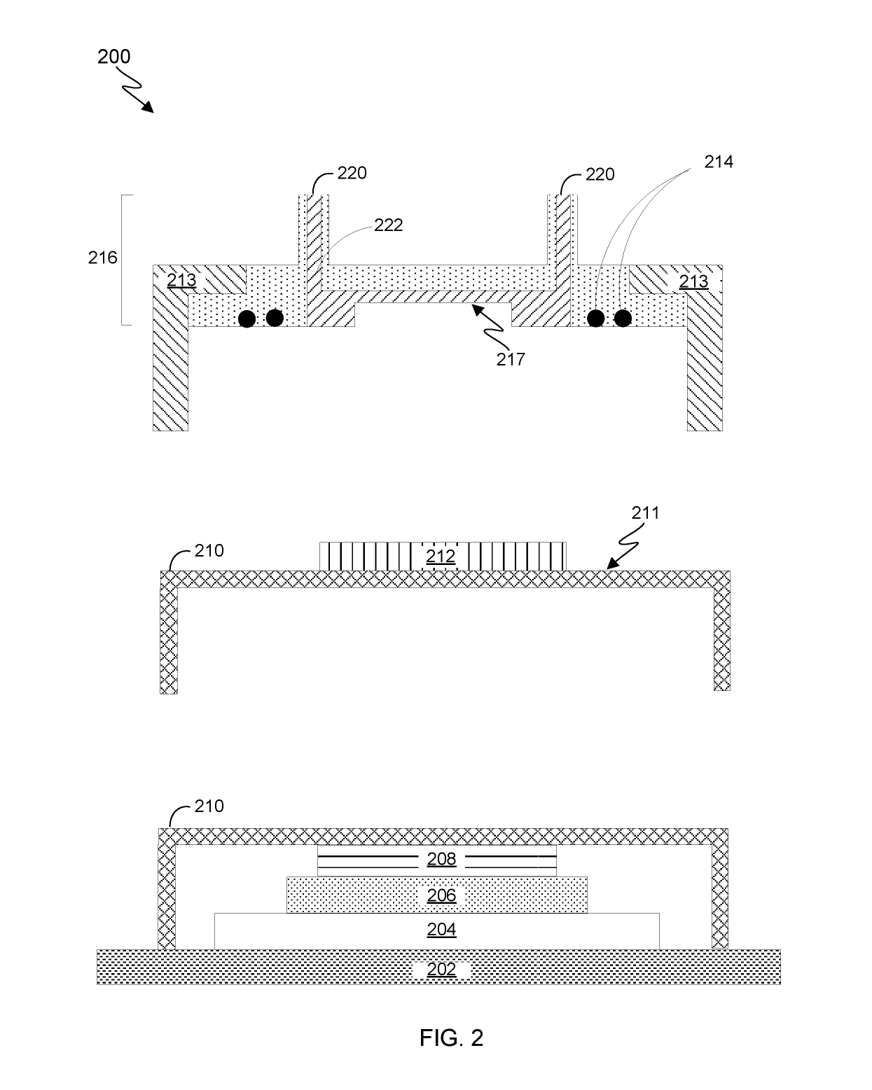

FIG. 2 depicts a partially exploded cross-sectional view of a more detailed embodiment of a water cooled module with integrated heat transferring structures, in accordance with an embodiment of the present invention.

In this exemplary embodiment, the electronic assembly 200 includes an electronic component, such as an integrated circuit chip 206 or stack of integrated circuit chips, mounted to a substrate 204, which is mounted to a board 202. Chip 206 may be composed of silicon. Chip 206 may be electrically connected to substrate 204 via an array of electrical interconnects and an under-fill or an adhesive may be used to bond chip 206 to substrate 204. A module lid 210 is fitted over chip 206, with a TIM1 208 placed between the chip 206 and the underside of module lid 210. In this exemplary embodiment, module lid 210 is constructed to have heat transfer enhancing features, such as pins, fins, etc., (fins 212 depicted) which extend above the module lid surface 211.

In this exemplary embodiment, the electronic assembly 200 includes a water carrying manifold structure 216. Manifold structure 216 is placed over the top of module lid surface 211 and is sealed via seals 214, (e.g., external clamping and O-rings) which seal around the manifold structure 216, so that the bottom surface 217 of manifold structure 216 is sealed to the top of module lid surface 211 of module lid 210, and fins 212 fit into a void in bottom surface 217. In some embodiments, sealing force is applied by an external clamping structure 213 at the perimeter of manifold structure 216 or at the center of manifold structure 216. Manifold structure 216 can be composed of metal (e.g., copper, aluminum, etc.) or a polymer (e.g., polyphenylsulfone, polyethylene, polyvinyl chloride, Teflon, etc.). After sealing the manifold structure 216 to the module lid 210, water 222 is able to flow from an inlet to an outlet, via permanently attached or separable tubes 220 that extend from the manifold structure. The water 222 passing through the heat transfer features (e.g., fins 212) on top of the module lid 210 removes heat from the water cooled module and transfers the heat to the cooling fluid which passes through and around these features. Water 222 is passed from one side of the manifold structure 216 to the other side, to provide heat transfer away from module lid surface 211.

Some embodiments of the present invention may include one, or more, of the following features, characteristics and/or advantages: (i) eliminates a conductive cold plate bottom surfaced structure and a thermal interface layer (i.e., removes two thermal resistance layers); (ii) reduces the cost incurred due to the requirements on module lid flatness; (iii) ability of the manifold structure to have some flexibility; and (iv) a water cooling loop which is closer to the hot points of the module.

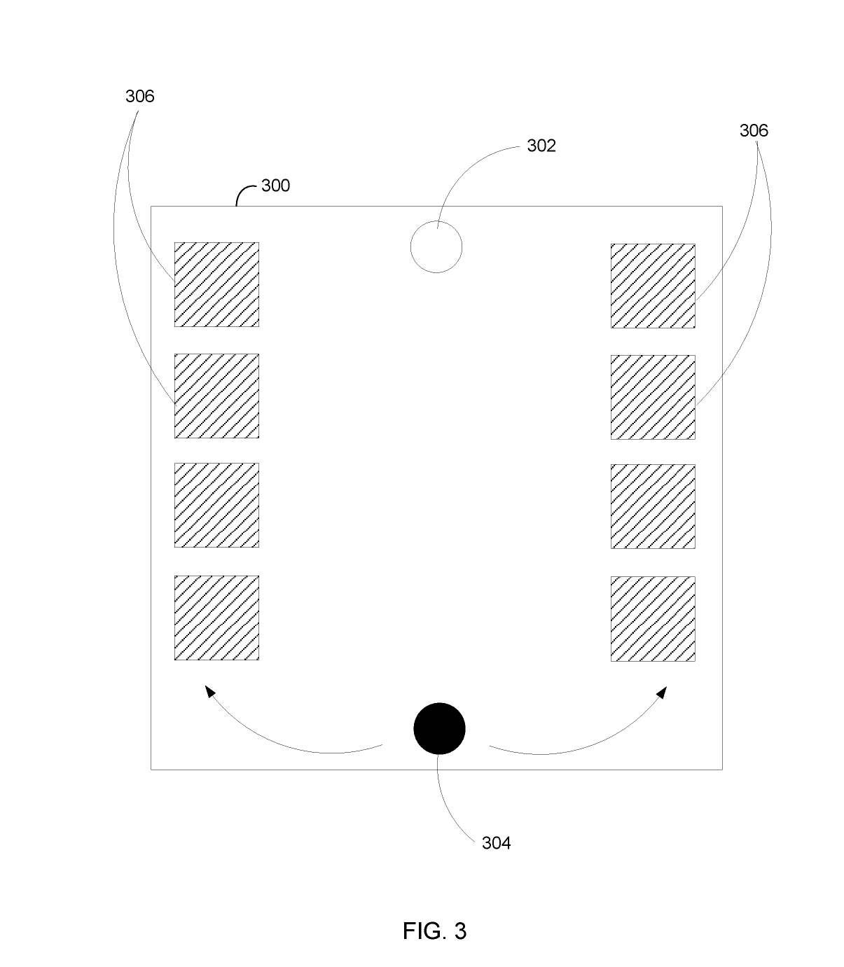

FIG. 3 depicts a plan view of a defined flow path integrated into a module lid of a chip 300, in accordance with one embodiment of the present invention.

In some embodiments, the heat transfer features can be designed to provide a directed water flow path that further improves the heat transfer away from the module, as depicted in FIG. 3. For example, the water flow path can be directed using manifold structure(s) 116, heat transferring features of the lid (e.g., fins 112), or any combination of both manifold structures 116 and heat transferring features. In some embodiments, the power map of the chip is known in advance, and the manifold structures 116 and/or heat transferring features are built in order to maximize the cooling in the areas with the highest power density (i.e., highest temperature). In this manner, the coldest liquid (e.g., fluid entry 304 in the example chip 300 of FIG. 3) can be directed, using the manifold structures 116 and heat transferring features, to areas of need (i.e., areas of highest heat flux) so that those areas can be cooled. For example, in a processor with two vertical rows of cores towards the perimeter of the chip 300, the highest heat flux areas 306 will occur in two vertical columns toward the edges of the chip 300. The coldest liquid at fluid entry 304 is forced to flow over the highest heat flux areas 306 by means of a combination of the manifold structures 116 and the heat transferring features, before cooling the rest of the chip 300. The coldest liquid flows outward toward the arrows, to cool the highest heat flux areas (i.e., the two vertical columns toward the edges of the chip 300 in this example) in order to improve thermal performance, and exits through fluid exit 302, which becomes the area of warmest fluid in this example, as the hottest fluid is gathered in that area.

Detailed description of embodiments of the claimed structures and methods are disclosed herein; however, it is to be understood that the disclosed embodiments are merely illustrative of the claimed structures and methods that may be embodied in various forms. In addition, each of the examples given in connection with the various embodiments is intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “on”, “over”, “overlying”, “atop”, “positioned on”, or “positioned atop” mean that a first element, such as a first structure, is present on a second element, such as a second structure, wherein intervening elements, such as an interface structure, may be present between the first element and the second element. The terms “direct contact”, “directly on”, or “directly over” mean that a first element, such as a first structure, and a second element, such as a second structure, are connected without any intermediary conducting, insulating, or semiconductor layers at the interface of the two elements. The terms “connected” or “coupled” mean that one element is directly connected or coupled to another element, or intervening elements may be present. The terms “directly connected” or “directly coupled” mean that one element is connected or coupled to another element without any intermediary elements present.

Having described the preferred embodiments of a liquid manifold structure for direct cooling of lidded electronics modules, which are intended to be illustrative and not limiting, it is noted that modifications and variations may be made by persons skilled in the art in light of the above teachings. It is, therefore, to be understood that changes may be made in the particular embodiments disclosed which are within the scope of the invention, as outlined by the appended claims.

In certain embodiments, the fabrication steps depicted above may be included on a semiconductor substrate consisting of many devices and one or more wiring levels to form an integrated circuit chip. The resulting integrated circuit chip(s) can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications, to advanced computer products having a display, a keyboard or other input device, and a central processor.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

What is claimed is:

1. A lidded electronic device comprising:
an electronic module, the electronic module comprising an integrated circuit chip coupled to a substrate;
a module lid, wherein the module lid comprises a heat transferring feature, and wherein the heat transferring feature is configured to extend above a top surface of the module lid; and
a manifold structure placed over the top surface of the module lid.

2. The lidded electronic device of claim 1, wherein the module lid is fitted over the integrated circuit chip, and wherein the module lid and the integrated circuit chip are coupled to a TIM1.

3. The lidded electronic device of claim 1, wherein the heat transferring feature comprises at least one of: a fin and a pin.

4. The lidded electronic device of claim 1, wherein the manifold structure is sealed to the top surface of the module lid with an O-ring and external clamping.

5. The lidded electronic device of claim 1, wherein the manifold structure comprises one of: copper, aluminum, polyphenylsulfone, polyethylene, polyvinyl chloride, and Teflon.

6. The lidded electronic device of claim 1, wherein the manifold structure is configured to allow water to flow from an inlet to an outlet, via a set of tubes, wherein the set of tubes are configured to extend upwards from the manifold structure.

7. The lidded electronic device of claim 1, wherein water flow is directed using at least one of: the manifold structure and the heat transferring feature.

8. The lidded electronic device of claim 1, wherein the electronic module, the module lid, and the heat transferring feature comprise one integral unit.

9. The lidded electronic device of claim 1, wherein the module lid is coupled to the manifold structure using a clamping feature, and wherein the clamping feature provides at least one of: an electrical connectivity and a physical seal.

10. The lidded electronic device of claim 1, wherein the module lid is mechanically coupled to the manifold structure using at least one of: screws and clips.

11. The lidded electronic device of claim 1, wherein the heat transferring feature is integral with the module lid.

12. The lidded electronic device of claim 1, wherein cooling is configured directly across the module lid.

13. The lidded electronic device of claim 7, wherein the water flow is directed to points of the electronic module comprising a highest temperature first.

14. A method for directing water flow in an electronic device, the method comprising:
based in part on a power map of an electronic device, configuring at least one of: a manifold structure and a heat transferring structure;
allowing water to flow through an inlet within the manifold structure, wherein the water is directed first to a point of the electronic device with a highest temperature; and
allowing the water to flow through an outlet within the manifold structure.

15. A lidded electronic device comprising:
an electronic module, the electronic module comprising an integrated circuit chip coupled to a substrate;
a module lid, wherein the module lid is fitted over the integrated circuit chip, and wherein the module lid and the integrated circuit chip are coupled to a TIM1; and
a manifold structure placed over a top surface of the module lid.

16. The lidded electronic device of claim 15, wherein the module lid is fitted over the integrated circuit chip, and wherein the module lid and the integrated circuit chip are coupled to the TIM1.

17. The lidded electronic device of claim 15, wherein the manifold structure is sealed to the top surface of the module lid with an O-ring and external clamping.

18. The lidded electronic device of claim 15, wherein the manifold structure is configured to allow water to flow from an inlet to an outlet, via a set of tubes, and wherein the set of tubes are configured to extend upwards from the manifold structure.

19. The lidded electronic device of claim 15, wherein the manifold structure comprises one of: copper, aluminum, polyphenylsulfone, polyethylene, polyvinyl chloride, and Teflon.

20. The lidded electronic device of claim 15, wherein the module lid is coupled to the manifold structure using a clamping feature, and wherein the clamping feature provides at least one of: an electrical connectivity and a physical seal.
